(19) United States
(12) Patent Application Publication
(10) Pub. No.: US 2026/0058103 A1
(43) Pub. Date: Feb. 26, 2026

(54) Filter Circuit and Plasma Processing Apparatus

(71) Applicant: Tokyo Electron Limited, Tokyo (JP)

(72) Inventor: Shuto WATANABE, Yamanashi (JP)

(21) Appl. No.: 19/295,439

(22) Filed: Aug. 8, 2025

(30) Foreign Application Priority Data
Aug. 24, 2024 (JP) 2024-140961

(51) Int. Cl. H01J 37/32

(52) U.S. Cl. CPC H01J 37/32422

(57) ABSTRACT

A filter circuit comprises an input port configured to have a first inner conductor and a first outer conductor, an output port configured to have a second inner conductor and a second outer conductor, a ground base configured to connect the first outer conductor of the input port and the second outer conductor of the output port, an antenna base configured to connect the first inner conductor of the input port and the second inner conductor of the output port, a ground fin configured to extend from the ground base toward the antenna base, and an antenna fin configured to extend from the antenna base toward the ground base with a gap provided between the ground fin and the antenna fin. The antenna fin includes a plurality of first rod-shaped bodies connected to the antenna base.

### CROSS-REFERENCE TO RELATED APPLICATIONS

This application claims priority to Japanese Patent Application No. 2024-140961 filed on Aug. 22, 2024, the entire contents of which are incorporated herein by reference.

### TECHNICAL FIELD

The present disclosure relates to a filter circuit and a plasma processing apparatus.

### BACKGROUND

It is disclosed that a plasma processing apparatus includes a heater power supply line, a coil and a capacitor for attenuating or blocking high-frequency noise entering a heater power supply line through a heating element, and a filter unit having a casing for accommodating the coil and the capacitor (see Japanese Laid-open Patent Publication No. 2014-99585).

### SUMMARY

The present disclosure provides a filter circuit and a plasma processing apparatus capable of reducing costs and suppressing processing waste.

A filter circuit according to one aspect of the present disclosure comprises an input port, an output port, a ground base, an antenna base, a ground fin and an antenna fin. The input port is configured to have a first inner conductor and a first outer conductor. The output port is configured to have a second inner conductor and a second outer conductor. The ground base is configured to connect the first outer conductor of the input port and the second outer conductor of the output port. The antenna base is configured to connect the first inner conductor of the input port and the second inner conductor of the output port. The ground fin is configured to extend from the ground base toward the antenna base. The antenna fin is configured to extend from the antenna base toward the ground base with a gap provided between the ground fin and the antenna fin. Further, the antenna fin includes a plurality of first rod-shaped bodies connected to the antenna base.

### BRIEF DESCRIPTION OF THE DRAWINGS

FIG. 1 is a schematic cross-sectional view showing a configuration example of a plasma processing apparatus according to a first embodiment of the present disclosure.

FIG. 2 is a perspective view showing an example of a filter circuit according to the first embodiment.

FIG. 3 is a cross-sectional view showing an example of an internal configuration of the filter circuit corresponding to the III-III cross section of FIG. 2.

FIG. 4 shows an example of machining of an inner conductor having a three-dimensional structure.

FIG. 5 shows an example of an inner conductor according to the first embodiment.

FIG. 6 shows an example of the inner conductor according to the first embodiment.

FIG. 7 shows an example of a dielectric according to the first embodiment.

FIG. 8 shows an example of an outer conductor according to the first embodiment.

FIG. 9 is a graph showing an example of frequency characteristics of a filter circuit according to the first embodiment.

FIG. 10 shows an example of an aperture ratio of an outer conductor.

FIG. 11 is a graph showing an example of a variation in a resonant frequency with respect to the aperture ratio of the outer conductor.

FIG. 12 is a graph showing an example of a variation in a resonant frequency with respect to the aperture ratio of the inner conductor.

FIG. 13 is a perspective view showing an example of a filter circuit according to a second embodiment.

FIG. 14 is a cross-sectional view showing an example of the XIV-XIV cross section of FIG. 13.

FIG. 15 is a cross-sectional view showing an example of the XV-XV cross section of FIG. 14.

FIG. 16 is a cross-sectional view showing an example of the XVI(XVII)-XVI(XVII) cross section of FIG. 14.

FIG. 17 is a cross-sectional view showing another example of the XVI(XVII)-XVI(XVII) cross section of FIG. 14.

### DETAILED DESCRIPTION

Hereinafter, embodiments of a filter circuit and a plasma processing apparatus will be described in detail with reference to the accompanying drawings. Further, the following embodiments are not intended to limit the present disclosure.

In the plasma processing apparatus, a power supply located outside the processing chamber is connected to the heater or the electrostatic chuck provided at the substrate support part that supports the substrate to be processed. Since the substrate support part constitutes the lower electrode for generating plasma, the high-frequency power for plasma generation may affect the power supply line to the electrostatic chuck or the heater. Therefore, a high-frequency filter including a coil and a capacitor is inserted in the power supply line. However, the high-frequency filter including a coil and a capacitor has a complex structure and large dimensions. In response thereto, it is considered to provide a high-frequency filter having a three-dimensional structure including, for example, an aluminum member and a dielectric. However, in a high-frequency filter of a three-dimensional structure, in the case of machining an aluminum member into a comb-tooth structure with a high aspect ratio, for example, the machining difficulty is high, and machining costs and machining waste may increase. In addition, in the high-frequency filter of a three-dimensional structure, the number of machined parts may increase due to the combination of a plurality of machined parts. Therefore, it is expected to reduce the cost and realize the suppression of processing waste material.

### First Embodiment

### <Configuration of Plasma Processing System>

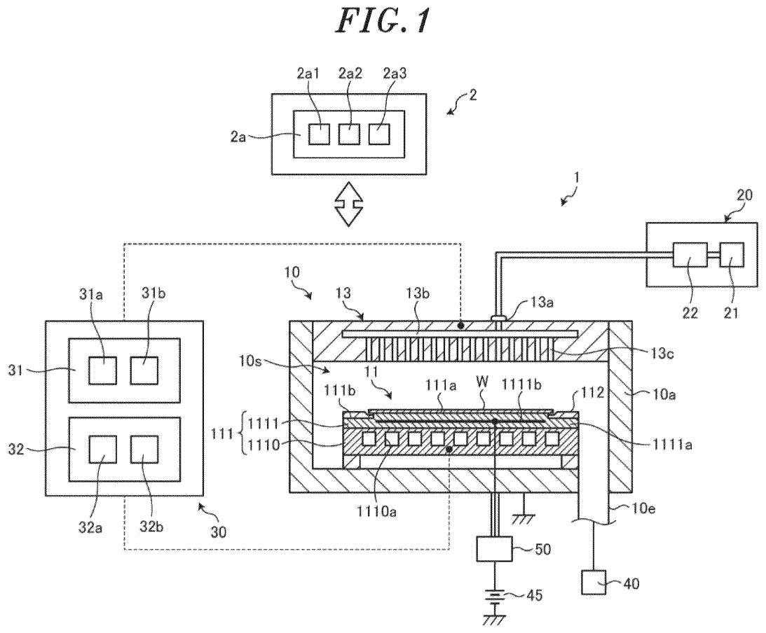

Hereinafter, a configuration example of a plasma processing system will be described. FIG. 1 is a schematic cross-sectional view showing a configuration example of a plasma processing apparatus according to a first embodiment of the present disclosure. As shown in FIG. 1, the plasma processing system includes a capacitively coupled plasma processing apparatus 1 and a controller 2. The capacitively coupled plasma processing apparatus 1 includes a plasma processing chamber 10, a gas supply part 20, a power supply 30, an exhaust system 40, a DC power supply 45, and a filter circuit 50. The plasma processing apparatus 1 further includes a substrate support part 11 and a gas introducing part. The gas introducing part is configured to introduce at least one processing gas into the plasma processing chamber 10. The gas introducing part includes a shower head 13. The substrate support part 11 is located in the plasma processing chamber 10. The shower head 13 is located above the substrate support part 11. In one embodiment, the shower head 13 constitutes at least a part of the ceiling of the plasma processing chamber 10. The plasma processing chamber 10 has a plasma processing space 10s defined by the shower head 13, a sidewall 10a of the plasma processing chamber 10, and a substrate support part 11. The plasma processing chamber 10 has at least one gas supply port for supplying at least one processing gas to the plasma processing space 10s, and at least one gas exhaust port for exhausting a gas from the plasma processing space 10s. The plasma processing chamber 10 is grounded. The shower head 13 and the substrate support part 11 are electrically insulated from the housing of the plasma processing chamber 10.

The substrate support part 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 in plan view. The substrate W is located on the central region 111a of the main body 111, and the ring assembly 112 is located on the annular region 111b of the main body 111 to surround the substrate W on the central region 111a of the main body 111. Thus, the central region 111a is also referred to as “substrate supporting surface” for supporting the substrate W, and the annular region 111b is also referred to as “ring supporting surface” for supporting the ring assembly 112.

In one embodiment, the main body 111 includes a base 1110 and an electrostatic chuck 1111. The base 1110 includes a conductive member. The conductive member of the base 1110 can function as a lower electrode. The electrostatic chuck 1111 is located on the base 1110. The electrostatic chuck 1111 includes a ceramic member 1111a and an electrostatic electrode 1111b located in the ceramic member 1111a. The ceramic member 1111a has a central region 111a. In one embodiment, the ceramic member 1111a also has the annular region 111b. Further, another member surrounding the electrostatic chuck 1111, such as an annular electrostatic chuck or an annular insulating member, may have the annular region 111b. In this case, the ring assembly 112 may be located on the annular electrostatic chuck or the annular insulating member, or may be located on both the electrostatic chuck 1111 and the annular insulating member. The electrostatic electrode 1111b is connected to the DC power supply 45 via the filter circuit 50. When a voltage is applied from the DC power supply 45 to the electrostatic electrode 1111b, an electrostatic attractive force is generated between the electrostatic chuck 1111 and the substrate W. Due to the generated electrostatic attractive force, the substrate W is attracted to the electrostatic chuck 1111 and held by the electrostatic chuck 1111.

Further, at least one RF/DC electrode connected to a radio frequency (RF) power supply 31 and/or a DC (Direct Current) power supply 32, which will be described later, may be located in the ceramic member 1111a. In this case, at least one RF/DC electrode functions as a lower electrode. When a bias RF signal and/or a DC signal, which will be described later, is supplied to at least one RF/DC electrode, the RF/DC electrode is also referred to as “bias electrode.” The conductive member of the base 1110 and at least one RF/DC electrode may function as a plurality of lower electrodes. Further, the electrostatic electrode 1111b may function as a lower electrode. Thus, the substrate support part 11 includes at least one lower electrode.

Further, the substrate support part 11 may include a temperature control module configured to control at least one of the electrostatic chuck 1111, the ring assembly 112, and the substrate W to a target temperature. The temperature control module may include a heater, a heat transfer medium, a channel 1110a, or a combination thereof. A heat transfer fluid such as brine or a gas flows through the channel 1110a. In one embodiment, the channel 1110a is formed in the base 1110, and one or multiple heaters are located in the ceramic member 1111a of the electrostatic chuck 1111. Further, the substrate support part 11 may include a heat transfer gas supply part configured to supply a heat transfer gas to a gap between the backside of the substrate W and the central region 111a.

The shower head 13 is configured to introduce at least one processing gas from the gas supply part 20 into the plasma processing space 10s. The shower head 13 has at least one gas supply port 13a, at least one gas diffusion space 13b, and a plurality of gas inlet ports 13c. The processing gas supplied to the gas supply port 13a passes through the gas diffusion space 13b and is introduced into the plasma processing space 10s from the plurality of gas inlet ports 13c. Further, the shower head 13 includes at least one upper electrode. The gas introducing part may include, in addition to the shower head 13, one or multiple side gas injectors (SGI) attached to one or multiple openings formed in the sidewall 10a.

The gas supply part 20 may include at least one gas source 21 and at least one flow rate controller 22. In one embodiment, the gas supply part 20 is configured to supply at least one process gas from the corresponding gas source 21 to the shower head 13 via the corresponding flow rate controller 22. The flow rate controllers 22 may include, for example, a mass flow controller or a pressure-controlled flow rate controller. Further, the gas supply part 20 may include one or more flow rate modulation devices for modulating the flow rate of at least one process gas or causing it to pulsate.

The power supply 30 includes an RF power supply 31 connected to the plasma processing chamber 10 via at least one impedance matching circuit. The RF power supply 31 is configured to supply at least one RF signal (RF power) to at least one lower electrode and/or at least one upper electrode. Accordingly, plasma is produced from at least one processing gas supplied to the plasma processing space 10s. Thus, the RF power supply 31 can function as at least a part of a plasma generator configured to generate plasma from one or more processing gases in the plasma processing chamber 10. By supplying a bias RF signal to at least one lower electrode, a bias potential is generated at the substrate W, and ion components in the generated plasma can be attracted to the substrate W.

In one embodiment, the RF power supply 31 includes a first RF generator 31a and a second RF generator 31b. The first RF generator 31a is connected to at least one lower electrode and/or at least one upper electrode via at least one impedance matching circuit, and is configured to generate a source RF signal (source RF power) for plasma generation. In one embodiment, the source RF signal has a frequency in the range of 10 MHz to 300 MHz. In one embodiment, the first RF generator 31a may be configured to generate a plurality of source RF signals having different frequencies. The generated one or multiple source RF signals are provided to at least one lower electrode and/or at least one upper electrode.

The second RF generator 31b is connected to at least one lower electrode via at least one impedance matching circuit and configured to generate a bias RF signal (bias RF power). The frequency of the bias RF signal may be the same as or different from the frequency of the source RF signal. In one embodiment, the bias RF signal has a frequency lower than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or multiple bias RF signals are provided to at least one lower electrode. Further, in various embodiments, at least one of the source RF signal and the bias RF signal may pulsate.

Further, the power supply 30 may include a DC power supply 32 connected to the plasma processing chamber 10. The DC power supply 32 includes a first DC generator 32a and a second DC generator 32b. In one embodiment, the first DC generator 32a is connected to at least one lower electrode and configured to generate a first DC signal. The generated first DC signal (bias DC signal) is applied to at least one lower electrode. In one embodiment, the second DC generator 32b is connected to at least one upper electrode and configured to generate a second DC signal. The generated second DC signal is applied to at least one upper electrode.

In various embodiments, at least one of the first and second DC signals may pulsate. In this case, a sequence of voltage pulses is applied to at least one lower electrode and/or at least one upper electrode. The voltage pulse may have a rectangular pulse waveform, a trapezoidal pulse waveform, a triangular pulse waveform, or a combination thereof. In one embodiment, a waveform generator for generating a sequence of voltage pulses from the DC signal is connected between the first DC generator 32a and at least one lower electrode. Thus, the first DC generator 32a and the waveform generator constitute a voltage pulse generator. When the second DC generator 32b and the waveform generator constitute a voltage pulse generator, the voltage pulse generator is connected to at least one upper electrode. The voltage pulses may have positive polarity or negative polarity. Further, the sequence of voltage pulses may include one or multiple positive polarity voltage pulses and one or multiple negative polarity voltage pulses in one cycle. The first and second DC generators 32a and 32b may be provided in addition to the RF power supply 31, or the first DC generator 32a may be provided instead of the second RF generator 31b.

The exhaust system 40 may be connected to, for example, a gas exhaust port 10e provided at the bottom portion of the plasma processing chamber 10. The exhaust system 40 may include a pressure control valve and a vacuum pump. The pressure in the plasma processing space 10s is controlled by the pressure control valve. The vacuum pump may include a turbo molecular pump, a dry pump, or a combination thereof.

The filter circuit 50 removes the effect of the high-frequency power for plasma generation or the high-frequency power for bias on the DC power supply 45 when plasma is generated in the plasma processing space 10s. The filter circuit 50 allows the passage of the DC applied from the DC power supply 45 to the electrostatic electrode 1111b, and blocks the RF power flowing in the reverse direction from the electrostatic electrode 1111b.

The controller 2 processes computer-executable instructions that cause the plasma processing apparatus 1 to perform various steps described in the present disclosure. The controller 2 may be configured to control individual components of the plasma processing apparatus 1 to perform various steps described herein. In one embodiment, the controller 2 may be partially or entirely included in the plasma processing apparatus 1. The controller 2 may include a processing part 2a1, a storage part 2a2, and a communication interface 2a3. The controller 2 is realized by, for example, a computer 2a. The processing part 2a1 may be configured to read a program from the storage part 2a2 and execute the read program to perform various control operations. The program may be stored in the storage part 2a2 in advance, or may be acquired via a medium when necessary. The acquired program is stored in the storage part 2a2, and is read from the storage part 2a2 and executed by the processing part 2a1. The medium may be various storage media that are readable by the computer 2a, or may be a communication line connected to the communication interface 2a3. The processing part 2a1 may be a central processing unit (CPU). The storage part 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

### <Structure of Filter Circuit 50>

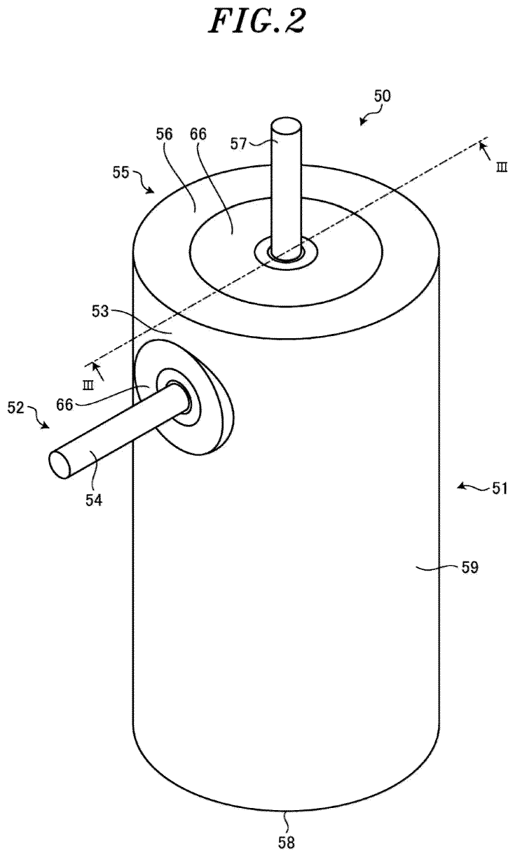

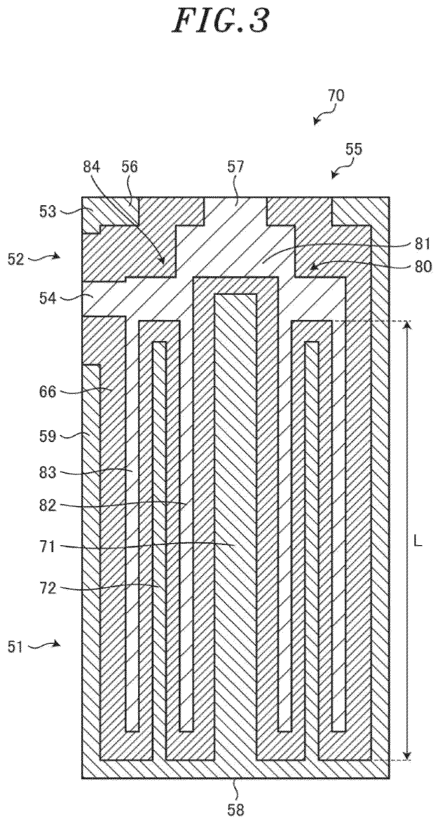

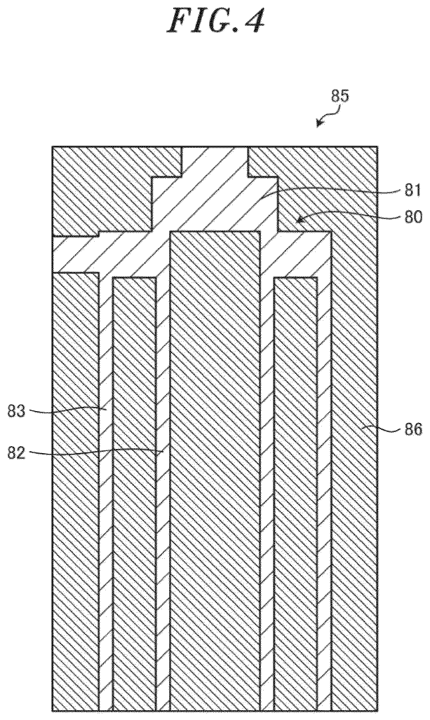

Next, the filter circuit 50 will be described in detail with reference to FIGS. 2 to 8. In the description of the filter circuit 50, FIGS. 3 and 4 are used to describe a filter circuit 70 using an antenna and a ground fin formed by machining an aluminum member. Then, the differences between the filter circuit 70 according to the present embodiment and the filter circuit 50 will be described. FIG. 2 is a perspective view showing an example of a filter circuit according to the first embodiment. As shown in FIG. 2, the filter circuit 50 has a housing 51. The housing 51 is made of a conductor such as aluminum or copper. Further, the housing 51 has an input port 52 and an output port 55. In the present embodiment, the RF power is blocked, so that the side connected to the electrostatic electrode 1111b will be described as the input port 52 and the side connected to the DC power supply 45 will be described as the output port 55, with respect to the flow direction of the RF power. The connection destinations of the input port 52 and the output port 55 may be changed.

The input port 52 and the output port 55 include outer conductors 53 and 56 and inner conductors 54 and 57, respectively. In other words, the input port 52 and the output port 55 have a coaxial structure. The housing 51 is electrically connected to the outer conductors 53 and 56, and is at ground potential together with the grounded plasma processing chamber 10 via the coaxial cable connected to the input port 52 or the frame where the filter circuit 50 is installed. The housing 51 has a cylindrical shape, and the input port 52 is formed on a cylindrical side surface 59. The housing 51 may have a tubular shape with a quadrilateral cross section. The output port 55 is formed at the end of the cylindrical housing 51 on the side where the input port 52 is formed, and a ground base 58, which is the other end, is formed in a disc shape to close the cylindrical housing 51. In the example of FIG. 2, the heights of a dielectric 66 and the end surfaces of the outer conductors 53 and 56 are approximately the same as the height of the end surface of the housing 51, and the inner conductors 54 and 57 are connected as terminals. However, the shapes of the input port 52 and the output port 55 may be changed appropriately depending on the connection destination. For example, the input port 52 and the output port 55 may be coaxial connectors or the like.

In other words, the input port 52 has a first inner conductor (inner conductor 54) and a first outer conductor (outer conductor 53). The output port 55 has a second inner conductor (inner conductor 57) and a second outer conductor (outer conductor 56). The ground base 58 is configured to connect the first outer conductor (outer conductor 53) on the input port 52 side to the second outer conductor (outer conductor 56) on the output port 55 side.

FIG. 3 is a cross-sectional view showing an example of an inner configuration of a filter circuit corresponding to the III-III cross section in FIG. 2. In FIG. 3, the cross section of the filter circuit 70 using an antenna 80 formed by machining an aluminum member as an antenna provided in the housing 51 will be described. The filter circuit 70 is compared with the filter circuit 50 of the present embodiment. An antenna 60 to be described later is replaced with the antenna 80, and ground fins 91 and 92 to be described later are replaced with ground fins 71 and 72.

The ground fins 71 and 72, which are made of a conductor such as aluminum or copper and protrude into the housing 51, are connected to the ground base 58. The ground fin 71 is an example of a second rod-shaped body, and has a columnar shape, for example. The ground fin 72 is provided to protrude in a cylindrical shape into the housing 51 around the ground fin 71. In other words, the ground fins 71 and 72 have a columnar shape and a cylindrical shape that are centric, for example.

The antenna 80 is provided in the housing 51. The antenna 80 has an antenna base 81, an antenna fin 82 formed to surround the ground fin 71, and an antenna fin 83 formed to surround the ground fin 72. The antenna fins 82 and 83 are connected to the antenna base 81. The ground fins 71 and 72 and the antenna fins 82 and 83 are arranged coaxially. The antenna 80 is made of a conductor such as aluminum or copper, and has a cylindrical shape with one end closed by the antenna base 81. In other words, the antenna 80 is a double cylindrical multipole antenna in which the antenna fin 82 and the antenna fin 83 are connected by the antenna base 81. In other words, the antenna 80 is an antenna (coaxial insertion multipole antenna) that does not radiate electromagnetic waves at a frequency to be blocked. Further, the antenna 80 may also be a cylindrical monopole antenna in which the antenna fin 82 is connected to the antenna base 81.

The antenna base 81 has a disc shape, and the center thereof is convex to offset the output port 55. The inner conductor 54 is connected to the side surface of the antenna base 81. The inner conductor 57 is connected to the upper surface of the antenna base 81. In other words, the inner conductor (input side conductor) 54 of the input port 52, the inner conductor (output side conductor) 57 of the output port 55, and the antenna 80 form a power supply line 84 insulated from the housing 51. The power supply line 84 is a path for supplying a DC power from the DC power supply 45 to the electrostatic electrode 1111b.

A dielectric 66 is provided between the housing 51 and the power supply line 84. In other words, the dielectric 66 is filled between the ground fin 71 and the antenna fin 82, between the antenna fin 82 and the ground fin 72, between the ground fin 72 and the antenna fin 83, between the antenna fin 83 and the cylindrical side surface 59, and between the tip ends of the antenna fins 82 and 83 and the ground base 58. Similarly, the dielectric 66 is filled between the outer conductor 53 and the inner conductor 54 of the input port 52, and between the outer conductor 56 and the inner conductor 57 of the output port 55. For example, poly tetra fluoro ethylene (PTFE) can be used as the dielectric 66.

Further, in the antenna 80, the space between the cylindrical side surface 59 and the ground fins 71 and 72 and the antenna fins 82 and 83 forms a choke structure based on the length of a quarter wavelength of the electromagnetic wave to be blocked, a so-called λ/4 choke. In other words, since the electromagnetic wave to be blocked reciprocates along a transmission path length W₁, the antenna 80 becomes a half-wave antenna that is twice the transmission path length W₁. In this case, a length L from the antenna base 81 to the ground base 58 is expressed by the following Equation (1) and Equation (2), and the transmission path length W₁ is expressed by the following Equation (3). Further, λ_{g} is the wavelength of the electromagnetic waves, and δ₁ is a parameter for fine adjustment.

$$L = ( {λ}_{g} / 16 ) + {δ}_{1} \qquad ( 1 )$$

$$- ( 3 / 100 ) {λ}_{g} ≦ {6}_{1} ≦ ( 3 / 100 ) {λ}_{g} \qquad ( 2 )$$

$${W}_{1} = L \times 4 \qquad ( 3 )$$

FIG. 4 shows an example of machining the inner conductor of a three-dimensional structure. As shown in FIG. 4, in the manufacturing process of the antenna 80, a cylindrical aluminum member 85 is machined. Further, FIG. 4 shows a longitudinal cross section of the cylindrical aluminum member 85. In this case, it is difficult to process the antenna fins 82 and 83 because a cylindrical part with a comb-tooth structure having a high aspect ratio is cut from the columnar aluminum member 85. In addition, the amount of a to-be-cut portion 86 around the antenna base 81 is large. If the amount of the to-be-cut portion 86 is large, the processing cost and the processing waste increase. Hence, in the first embodiment, an antenna 60 is used instead of the antenna 80.

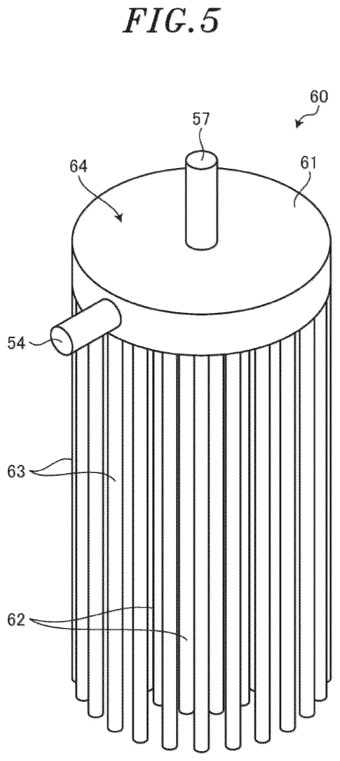

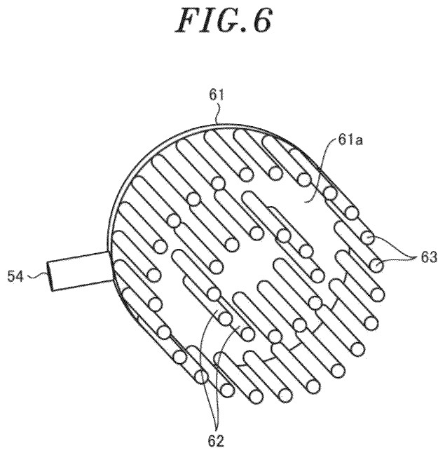

FIGS. 5 and 6 show an example of an inner conductor according to the first embodiment. As shown in FIGS. 5 and 6, the antenna 60 of the filter circuit 50 of the first embodiment has an antenna base 61 and antenna fins 62 and 63. The antenna base 61 corresponds to the antenna base 81 of the antenna 80. In addition, the inner conductor 57 of the output port 55 is connected to the disc-shaped central portion (upper surface side in FIG. 5) of the antenna base 61. The inner conductor 54 of the input port 52 is connected to the side surface of the antenna base 61. In other words, the antenna fins 62 and 63 correspond to the antenna fins 82 and 83 of the antenna 80. The inner conductor (input side conductor) 54 of the input port 52, the inner conductor (output side conductor) 57 of the output port 55, and the antenna 60 form a power supply line 64 insulated from the housing 51. The antenna fins 62 are an example of a plurality of first rod-shaped bodies, and the antenna fins 63 are an example of a plurality of fourth rod-shaped bodies. The shapes of the inner conductors 54 and 57 and the antenna base 61 (the shape of the power supply line 64) may be changed appropriately depending on the connection destination or the processing method.

The plurality of rod-shaped bodies of the antenna fins 62 and 63 are connected to a bottom surface 61a of the antenna base 61 in a concentric shape, for example. The plurality of rod-shaped bodies of the antenna fins 62 and 63 may be, for example, general-purpose metal spacers. Each of the rod-shaped bodies has a screw formed at one end. The rod-shaped bodies of the antenna fins 62 and 63 may be, for example, metal spacers of the same size. Further, the diameter of the rod-shaped bodies of the antenna fins 62 and 63 may be approximately the same as the thickness of the antenna fins 82 and 83. Similarly to the antenna 80, the antenna 60 may be a cylindrical monopole antenna including a plurality of rod-shaped bodies, in which the antenna fins 62 are connected to the antenna base 61.

A plurality of holes for connecting the antenna fins 62 and 63 are formed in the bottom surface 61a of the antenna base 61. The plurality of holes are tapped so that the antenna fins 62 and 63 can be screwed. Further, the frequency characteristics of the filter circuit 50 may be changed by adjusting the positions of the holes. For example, it is possible to adjust the center frequency of the high-frequency filter or adjust the filter width by providing some of the rod-shaped bodies of the antenna fins 62 and 63 inside or outside the circumferences of the concentric circles. Further, by providing the plurality of holes for connecting the antenna fins 62 and 63 inside or outside the circumferences of the concentric circles in advance as well as on the circumferences of the concentric circles, it can be reconstructed as a filter circuit having certain characteristics. Further, the rod-shaped bodies of the antenna fins 62 and 63 may have a circular, hexagonal or fan-shaped cross-sectional shape. Further, the rod-shaped bodies of the antenna fins 62 and the rod-shaped bodies of the antenna fins 63 may have different diameters in the cross section, or may have different cross-sectional shapes.

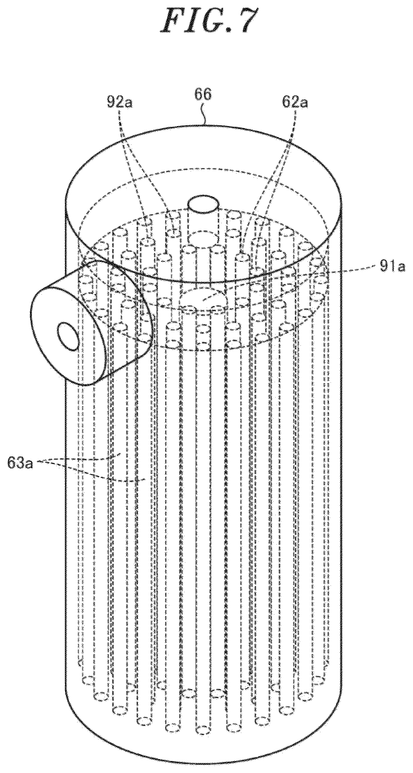

FIG. 7 shows an example of a dielectric material according to the first embodiment. As shown in FIG. 7, the dielectric 66 fills the inside of the housing 51, and has a plurality of holes 62a and 63a corresponding to the rod-shaped bodies of the antenna fins 62 and 63, and a plurality of holes 91a and 92a corresponding to the rod-shaped bodies of the ground fins 91 and 92 to be described later. The dielectric 66 includes a plurality of members, for example. When the upper member in FIG. 7 is removed, the plurality of holes 62a and 63a become visible, and the rod-shaped bodies of the antenna fins 62 and 63 can be inserted into the holes 62a and 63a. Further, the rod-shaped bodies of the ground fins 91 and 92 can be inserted into the holes 91a and 92a from the lower side in FIG. 7.

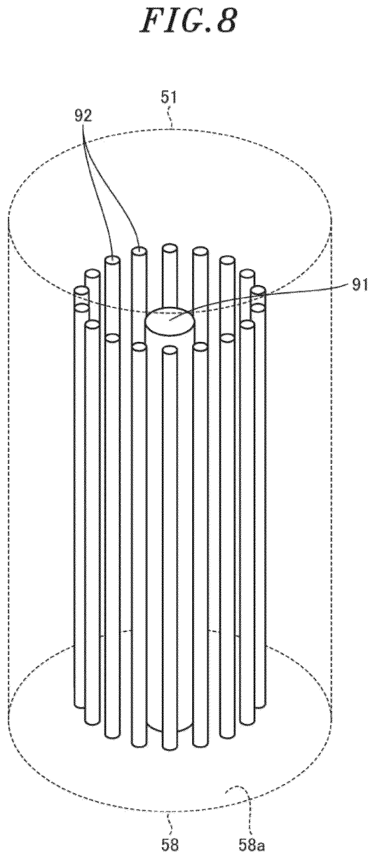

FIG. 8 shows an example of an outer conductor according to the first embodiment. The ground fins 91 and 92 of the filter circuit 50 shown in FIG. 8 correspond to the ground fins 71 and 72 of the filter circuit 70. The lower ends of the ground fins 91 and 92 in FIG. 8 are connected to aa surface 58a of the ground base 58 on the inner side of the housing 51. The ground fin 91 is an example of the second rod-shaped body, and has a cylindrical shape, for example. The ground fins 92 are provided such that a plurality of rod-shaped bodies arranged in a cylindrical shape around the ground fin 91 protrude into the housing 51. The ground fins 92 are an example of a plurality of third rod-shaped bodies. Similarly to the plurality of rod-shaped bodies of the antenna fins 62 and 63, the ground fins 92 may be general-purpose metal spacers. In other words, the ground fins 91 and 92 are a plurality of rod-shaped bodies arranged in a columnar shape and a cylindrical shape that are concentric, for example. The antenna 60 and the ground fins 71 and 72 may be combined to form a filter circuit.

In other words, the antenna base 61 is configured such that the first inner conductor (the inner conductor 54) on the input port 52 side and the second inner conductor (the inner conductor 57) on the output port 55 side are connected. In addition, the ground fins (the ground fins 91 and 92) are configured to extend from the ground base 58 toward the antenna base 61. The antenna fins (the antenna fins 62 and 63) are configured to extend from the antenna base 61 toward the ground base 58 while being spaced apart from the ground fins. The antenna fin includes the plurality of first rod-shaped bodies (the antenna fin 62) connected to the antenna base 61. The ground fin includes the second rod-shaped body (the ground fin 91) connected to the ground base 58, and the antenna fin includes the plurality of first rod-shaped bodies (the antenna fin 62) arranged to surround the second rod-shaped body. The ground fins include the plurality of third rod-shaped bodies (the ground fins 92) connected to the ground base 58 to surround the plurality of first rod-shaped bodies (the antenna fins 62).

The antenna fin includes the plurality of fourth rod-shaped bodies (the antenna fins 63) connected to the antenna base 61 to surround the plurality of third rod-shaped bodies (the ground fins 92). The plurality of first rod-shaped bodies (the antenna fins 62) and the plurality of fourth rod-shaped bodies (the antenna fins 63) of the antenna fin operate as a multipole antenna. The ground base 58 forms a part of the housing 51 of the filter circuit 50, and the inside of the housing 51 is filled with the dielectric 66. The dielectric 66 has holes (the holes 91a, 92a, 62a, and 63a) corresponding to the ground fin (the ground fins 91 and 92) and the antenna fin (the antenna fins 62 and 63).

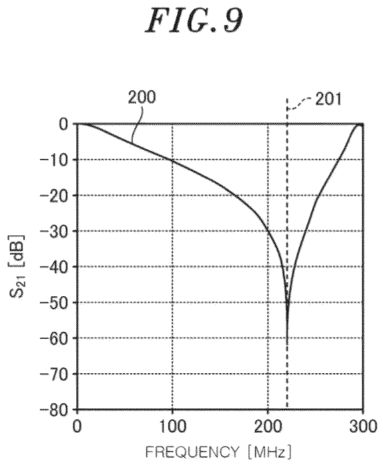

Next, the frequency characteristics of the filter circuit 50 will be described with reference to FIG. 9. FIG. 9 is a graph showing an example of the frequency characteristics of the filter circuit according to the first embodiment. In a graph 200 shown in FIG. 9, the frequency characteristics of the filter circuit 50 are expressed as an S parameter S₂₁. In FIG. 9, the vertical axis of the graph represents S₂₁ (insertion loss), and the attenuation amount increases toward the negative side. In addition, in FIG. 9, the fundamental frequency (220 MHz) of the electromagnetic waves to be blocked is expressed as a fundamental frequency 201. As shown in the graph 200, at the fundamental frequency of 220 MHz, the attenuation amount of the filter circuit 50 becomes maximum. and the insertion loss becomes −62 dB. Further, the insertion loss in the range of 200 MHz to 240 MHz becomes-30 dB or less. In other words, the filter circuit 50 forms a band-stop filter with a center frequency of 220 MHz. Since the high frequency in a frequency band to be blocked is resonated by a three-dimensional circuit using a multipole antenna, a filter circuit for a high-output high-frequency power such as 1000 W in a very high frequency (VHF) band can be miniaturized to a simple structure. Further, since the power supply line 64 is insulated from the housing 51, the output of the DC power supply 45 can be applied to the electrostatic electrode 1111b without grounding. Further, in the present embodiment, in the frequency range where the insertion loss becomes −30 dB or less, it is possible to block electromagnetic waves (single peak waveform) whose frequency varies using FM modulation or the like, or electromagnetic waves (broadband waveform) of a plurality of frequencies generated as multitones. In addition, the filter circuit 50 may simultaneously attenuate and block the harmonics of the electromagnetic waves to be blocked, such as the third harmonic (660 MHz), together with the fundamental frequency (220 MHz).

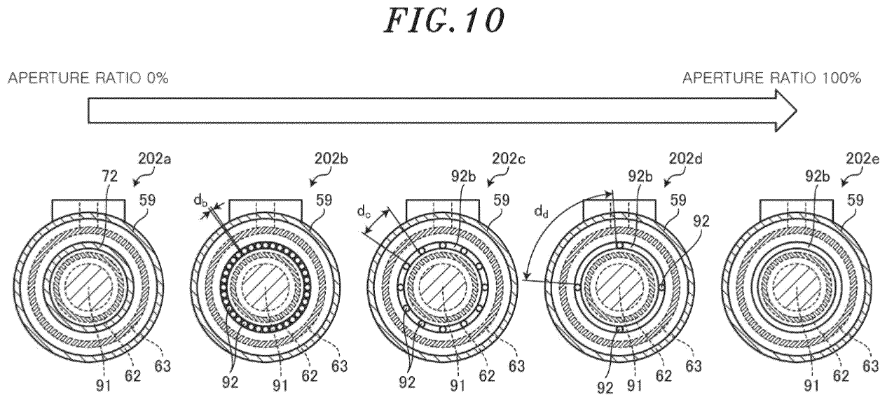

Next, the aperture ratios in the circumferential direction of the ground fins 92 and the antenna fins 62 will be described with reference to FIGS. 10 to 12. FIG. 10 shows an example of the aperture ratio of the outer conductor. In FIG. 10, the aperture ratios in the circumferential direction of the ground fins 92 in the cross section taken along the diameter direction of the cylindrical housing 51 will be described as states 202a to 202e starting from the aperture ratio of 0% toward the aperture ratio of 100%. In the corresponding cross sections, the dielectric 66 is omitted, and the positions (areas) of the ground fin 91, the antenna fins 62, the ground fins 72 and 92, the antenna fins 63, and the side surface 59 are illustrated in that order as dotted or solid lines from the center of the cylindrical housing 51. In other words, the plurality of rod-shaped bodies of the antenna fins 62 and 63 are omitted, and the areas where the plurality of rod-shaped bodies exist are illustrated as the cross sections surrounded by dotted lines. Further, the ground fins 92 are not shaded to show the distance (gap) between the rod-shaped bodies.

In the state 202a, the aperture ratio is 0%, and there is no gap in the circumferential direction of the ground fins 92, so that it is equivalent to the cylindrical ground fin 72 that is continuous in the circumferential direction. In the state 202b, the plurality of rod-shaped bodies of the ground fins 92 are arranged at a gap d_{b} in the circumferential direction. In the state 202c, the plurality of rod-shaped bodies of the ground fins 92 are arranged at a gap de greater than the gap d_{b} in the state 202b in the circumferential direction. In the state 202c, there are many areas 92b where the rod-shaped bodies of the ground fins 92 do not exist in the circumferential direction, and the aperture ratio exceeds 50%. The areas 92b are filled with the omitted dielectric 66. In the state 202d, the plurality of rod-shaped bodies of the ground fins 92 are arranged at a gap da greater than the gap d_{c} in the state 202c in the circumferential direction. In the state 202e, the aperture ratio is 100%, and the rod-shaped bodies of the ground fins 92 do not exist.

Here, the gap d (the gaps d_{b} to d_{d} described above) between the plurality of rod-shaped bodies (the third rod-shaped bodies) of the ground fins 92 can be defined by the following Equation (4). Similarly, the plurality of rod-shaped bodies (the first rod-shaped bodies) of the antenna fins 62 can be defined by the following Equation (4).

$$d < A \frac{{δ}_{2}}{( 1 + {δ}_{2} )} \cdot \frac{λ}{\sqrt{{ε}_{r}}} \qquad ( 4 )$$

In Equation (4), d indicates the gap between the plurality of rod-shaped bodies (third rod-shaped bodies) of the ground fins 92 or the plurality of rod-shaped bodies (first rod-shaped bodies) of the antenna fins 62, and λ indicates the wavelength of the resonance frequency f₀ of the filter circuit 50. In Equation (4), εᵣ indicates the relative permittivity of the dielectric 66 (medium) between the ground fins 91 and 92 and the antenna fins 62 and 63, δ₂ indicates a variation in the resonance frequency f₀, and A indicates a coefficient based on δ₂. A may be, e.g., the variation δ₂/the aperture ratio. For example, if the variation δ₂ is 5% and the aperture ratio is 60%, the coefficient A becomes 0.08. The resonant frequency f₀ corresponds to the frequency to be blocked in the filter circuit 50, and may be simply referred to as the filter frequency.

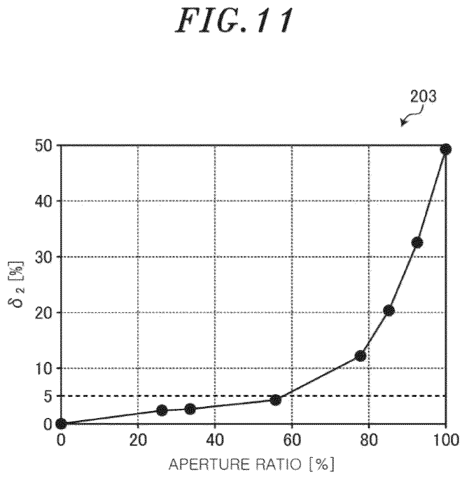

FIG. 11 is a graph showing an example of the variation in the resonant frequency depending on the aperture ratio of the outer conductor. As shown in a graph 203 of FIG. 11, the variation δ₂ in the resonant frequency f₀ tends to increase according to the aperture ratio of the ground fins 92. If the variation δ₂ in the resonant frequency f₀ is set to 5% or less compared to the cylindrical ground fin 72 (tolerance rate 5% or less), the aperture ratio of the ground fins 92 can be increased to about 56%.

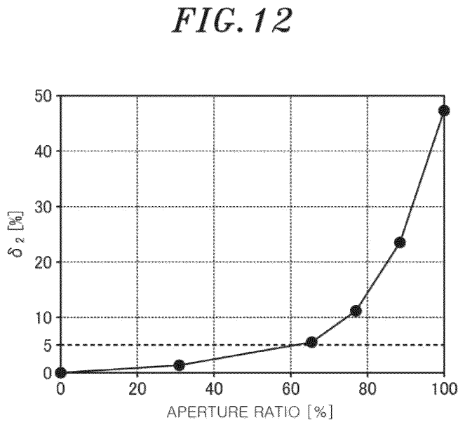

FIG. 12 is a graph showing an example of the variation in the resonant frequency with respect to the aperture ratio of the inner conductor. As shown in a graph 204 of FIG. 12, the variation δ₂ in the resonant frequency f0 tends to increase depending on the aperture ratio of the antenna fins 62. If the variation δ₂ in the resonant frequency f₀ is set to 5% or less compared to the cylindrical antenna fin 82 (tolerance rate 5% or less), the aperture ratio of the antenna fins 62 can be increased to about 60%. In this manner, the filter circuit 50 of the first embodiment can reduce costs and suppress processing waste. In other words, the filter circuit 50 can reduce material costs and processing difficulty (man-hours).

### Second Embodiment

In the first embodiment, the cylindrical filter circuit 50 is used as the filter circuit. However, a filter circuit 350 with a shorter width dimension may be used when it is installed along the longitudinal direction of the power supply line. An embodiment in this case will be described as a second embodiment. The plasma processing apparatus in the second embodiment is similar to the first embodiment except the filter circuit, so that the description of the redundant configurations and operations will be omitted.

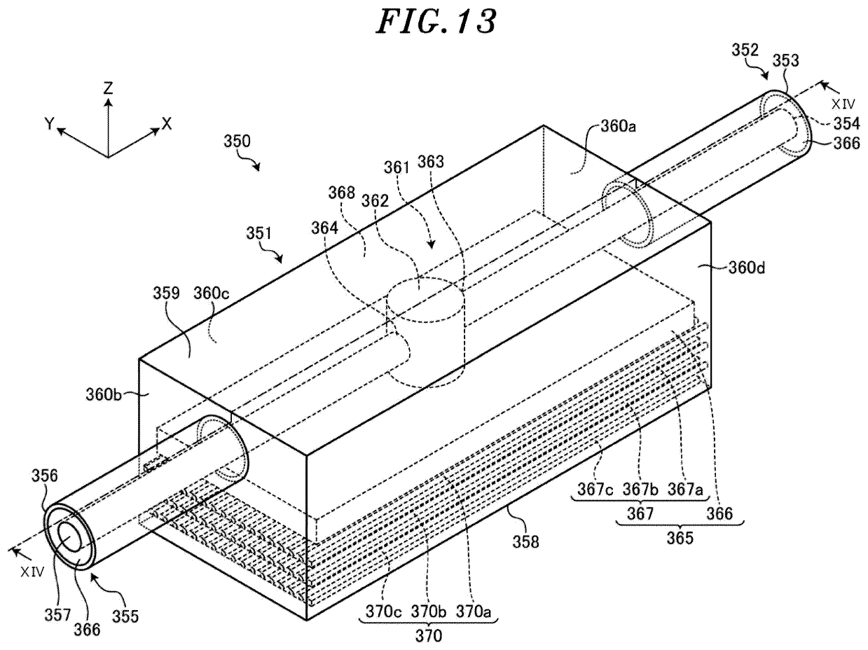

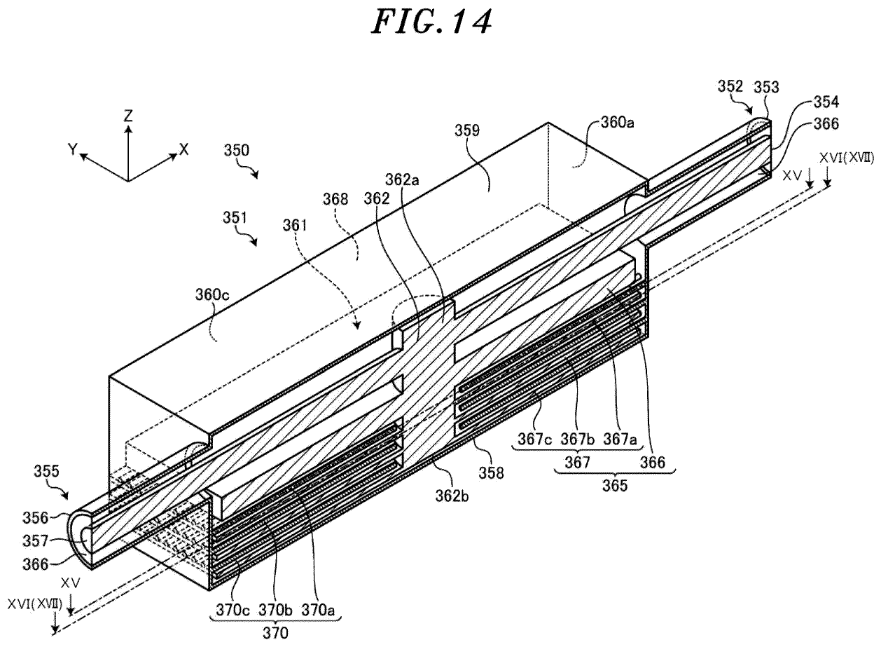

FIG. 13 is a perspective view showing an example of a filter circuit according to the second embodiment. FIG. 14 is a cross-sectional view showing an example of the XIV-XIV cross section of FIG. 13. In the following description, the longitudinal direction of the filter circuit 350 is set as the X direction along the X axis, and the lateral direction is set as the Y direction along the Y axis. The direction along the Z axis perpendicular to the X axis and the Y axis is set as the Z direction. The X direction is an example of the first direction, the Y direction is an example of the second direction, and the Z direction is an example of the third direction. In the cross sections shown in FIGS. 14 to 17, a case where air is used as a dielectric 368 to be described later is illustrated. As shown in FIGS. 13 and 14, the filter circuit 350 has a housing 351. The housing 351 is made of a conductor such as aluminum or copper. The housing 351 has an input port 352 and an output port 355. In the present embodiment, the high-frequency power is blocked, so that the side connected to the electrostatic electrode 1111b will be descried as the input port 352 and the side connected to the DC power supply 45 will be described as the output port 355 with respect to the flow direction of the high-frequency power. The connection destinations of the input port 352 and the output port 355 may be changed.

The input port 352 and the output port 355 include outer conductors 353 and 356 and inner conductors 354 and 357, respectively. In other words, the input port 352 and the output port 355 have a coaxial structure. The housing 351 is electrically connected to the outer conductors 353 and 356, and is at ground potential together with the grounded plasma processing chamber 10 via the coaxial cable connected to the input port 352 and the frame where the filter circuit 350 is installed. In other words, the housing 351 is formed of a conductor, and is provided with the input port 352 and the output port 355 including the outer conductors 353 and 356 and the inner conductors 354 and 357. The housing 351 is at ground potential together with the outer conductors 353 and 356 of the input port 352 and the output port 355. The housing 351 is formed in, for example, a rectangular parallelepiped shape, and has a bottom surface 358 and an upper surface 359 intersecting with the Z direction of the rectangular parallelepiped, side surfaces 360a and 360b intersecting with the X direction, and side surfaces 360c and 360d intersecting with the Y direction. In other words, the housing 351 is configured such that the internal space is expanded in the X direction and the Y direction in plan view (viewed from the Z direction). The corners of the internal space in the X direction and the Y direction may be rounded. Further, the housing 351 has the input port 352 formed on the side surface 360a, and the output port 355 formed on the side surface 360b opposite to the side surface 360a. The inner conductors 354 and 357 of the input port 352 and the output port 355 are connected to side surfaces 363 and 364 of an upper portion 362a of the antenna base 362 located substantially at the center of the plane in the X direction and the Y direction in the internal space of the housing 351, respectively. In other words, the input port 352 and the output port 355 extend in the X direction passing through the antenna base 362. Further, the inner conductor (input side conductor) 354 of the input port 352, the inner conductor (output side conductor) 357 of the output port 355, an antenna part 365, and the antenna base 362 form a power supply line 361 insulated from the housing 351. Further, the power supply line 361 is an example of a second power supply line, and constitutes a part of the first power supply line, which is a path for supplying a DC power from the DC power supply 45 to the electrostatic electrode 1111b.

The antenna base 362 connects the inner conductors 354 and 357, which are the input side conductor and the output side conductor, to the antenna part 365. The antenna base 362 is formed in a cylindrical shape, for example, and extends in the Z direction. The antenna part 365 is provided on the bottom surface 358 side in the Z direction of the inner conductors 354 and 357, and has a first fin 366 and a second fin 367. The second fin 367 includes a plurality of second fins 367a to 367c, for example. The first fin 366 and the second fin 367 are formed of a conductor such as plate-shaped aluminum or copper, and are connected to the antenna base 362 at substantially the center of the plane in the X direction and the Y direction. The first fin 366 is formed to be thicker than each of the second fins 367a to 367c, for example. Further, the first fin 366 may have the same thickness as each of the second fins 367a to 367c, for example. In other words, the antenna part 365 is provided to expand from the antenna base 362 in the X direction and the Y direction. The antenna part 365 is not in contact with the four side surfaces 360a to 360d of the housing 351. In other words, the antenna part 365 has a rectangular shape that is slightly smaller than the upper surface 359 in plan view (when viewed from the Z direction).

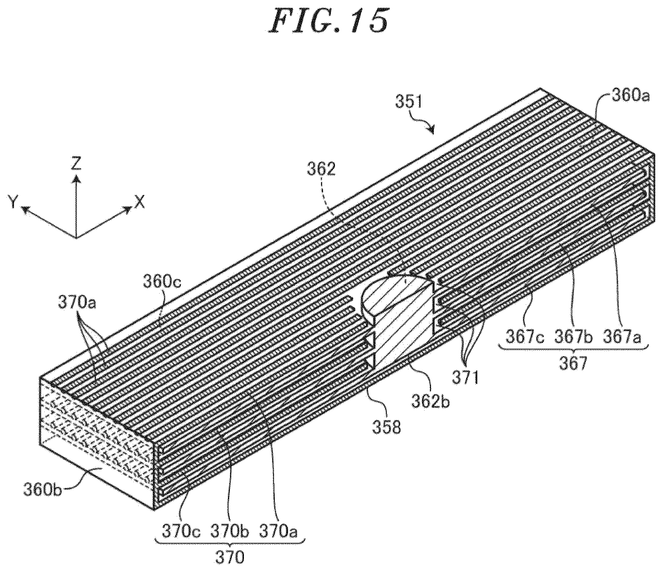

A partition part 370, which is made of a conductor such as aluminum or copper, connected to the housing 351, and partitions the internal space of the housing 351, is formed in the internal space of the housing 351. The partition part 370 includes a plurality of partition portions 370a to 370c, for example. The partition portions 370a to 370c are formed as a plurality of rod-shaped bodies, for example. Similarly to the ground fins 92 of the first embodiment, the rod-shaped bodies may be general-purpose metal spacers, for example. In other words, the partition part 370 includes a plurality of rod-shaped conductors such as aluminum or copper, and is connected to the side surfaces 360a and 360b. Further, the partition part 370 is spaced apart from the cylindrical antenna base 362 by a constant gap (gap 371 in FIG. 15 to be described later) in a ring shape.

In other words, the partition part 370 is an example of the ground fin, and the side surfaces 360a and 360b are an example of the ground base. The side surface 360a is an example of the first surface to which the first outer conductor (the outer conductor 353) on the input port 352 side is connected. Further, the side surface 360b is an example of the second surface facing the first surface and to which the second outer conductor (the outer conductor 356) on the output port 355 side is connected. In other words, the partition part 370 is an example of the ground fin that is connected to at least one of the first surface and the second surface of the ground base, and extends from one of the first surface and the second surfaces to the other surface. The ground fin includes a plurality of first rod-shaped bodies (the partition portions 370a to 370c) in the second embodiment that are connected to at least one of the first surface and the second surface. The plurality of first rod-shaped bodies (the partition portions 370a to 370c) in the second embodiment correspond to the second rod-shaped body (the ground fin 91) and the plurality of third rod-shaped bodies (the ground fins 92) in the first embodiment. Therefore, the gap between the plurality of first rod-shaped bodies (the partition portions 370a to 370c) in the second embodiment corresponds to the gap between the plurality of first rod-shaped bodies forming the partition portion 370a, for example. The gap can be defined by the Equation (4) in the first embodiment. Further, the ground base is the housing 351 that is configured such that the internal space expands in the first direction and the second direction perpendicular to the first direction in plan view.

The antenna part 365 and the partition part 370 are formed such that the first fin 366, the second fins 367a to 367c, and the partition portions 370a to 370c are alternately arranged in the XIV-XIV cross section. In other words, the antenna part 365 is connected to the inner conductors 354 and 357, which are the input side conductor and the output side conductor, and extends into the internal space to be stacked with the partition part 370. In other words, in the filter circuit 350, the space between the first fin 366 and the second fins 367a to 367c and the partition portions 370a to 370c and the bottom surface 358 has a transmission path length W₂ to form a choke structure based on the length of ¼ wavelength of the frequency to be blocked. In other words, in the filter circuit 350, the space between the housing 351 and the partition part 370 and the antenna part 365, which extends from the end portion of the first fin 366 in the X direction that is closest to the input port 352 and the output port 355 of the antenna part 365 to the center of an end portion 362b of the antenna base 362 to which the second fin 367c that is farthest from the input port 352 and the output port 355 is connected, forms a choke structure based on the length of ¼ wavelength of the electromagnetic wave to be blocked.

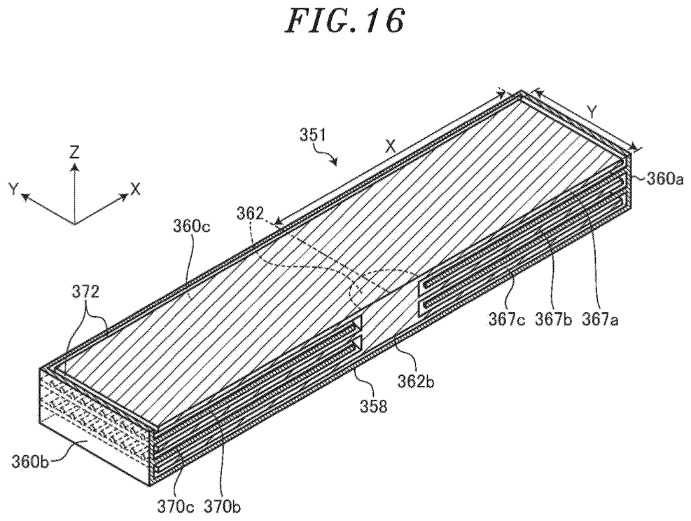

FIG. 15 is a cross-sectional view showing an example of the XV-XV cross section of FIG. 14. FIG. 16 is a cross-sectional view showing an example of the XVI(XVII)-XVI(XVII) cross section of FIG. 14. As shown in FIG. 15, the partition portions 370a to 370c connected to the housing 351 are installed to be spaced apart from the antenna base 362 by a constant gap 371. On the other hand, as shown in FIG. 16, the second fins 367a to 367c connected to the antenna base 362 are spaced apart from the side surfaces 360a to 360d of the housing 351 by a constant gap 372. As shown in FIGS. 13 and 14, the first fin 366 is spaced apart from the side surfaces 360a to 360d of the housing 351 by a constant gap, similarly to the second fins 367a to 367c. Here, the second fins 367a to 367c preferably have dimensions in which the total propagation length (path length) in the X direction is λ/4+a, λ being the wavelength of the electromagnetic wave. Further, α is a parameter for fine adjustment. On the other hand, the second fins 367a to 367c may have dimensions in which the total propagation length (path length) in the Y direction is sufficiently less than λ/4, A being the wavelength of the electromagnetic wave. For example, when the filter frequency is 220 MHz, the dimension X may be 55 mm and the dimension Y may be 25 mm in FIG. 16. In other words, the outer dimensions of the housing 351 in the X direction and in the Y direction are 110 mm and 50 mm, respectively.

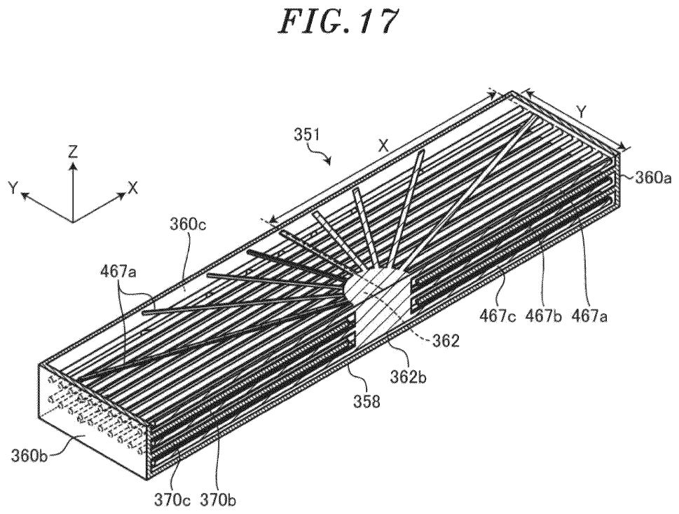

Further, the second fins 367a to 367c may be formed as a plurality of rod-shaped bodies connected radially to the antenna base 362. FIG. 17 is a cross-sectional view showing another example of the XVI(XVII)-XVI(XVII) cross section in FIG. 14. As shown in FIG. 17, the second fins 467a to 467c are formed as a plurality of rod-shaped bodies, and are connected radially to the antenna base 362. The tip ends of the second fins 467a to 467c are spaced apart from the side surfaces 360a to 360d of the housing 351 by a constant gap, similarly to the second fins 367a to 367c. Further, in the second fins 467a to 467c, the rod-shaped bodies may be bent in the X direction at the intermediate portions thereof.

In other words, the antenna base 362 is located at the center of the housing 351 in plan view. Further, the antenna fin includes a plurality of second rod-shaped bodies (the second fins 467a to 467c) in the second embodiment that are radially connected to the antenna base 362. The plurality of second rod-shaped bodies (the second fins 467a to 467c) in the second embodiment correspond to the plurality of first rod-shaped bodies (the antenna fins 62) in the first embodiment.

Further, as shown in FIG. 14, the filter circuit 350 has the dielectric 368 between the housing 351 and the power supply line 361. In other words, the space between the inner conductors 354 and 357 and the upper surface 359 and the side surfaces 360a to 360d, the space between the inner conductors 354 and 357 and the first fin 366, and the space between the first fin 366 and the partition portion 370a are filled with the dielectric 368. Similarly, the space between the second fins 367a to 367c and the partition portions 370a to 370c, the space between the second fin 367c and the bottom surface 358, and the space between the first fin 366 and the second fins 367a to 367c and the side surfaces 360a to 360d are filled with the dielectric 368. In the case of using a solid material the dielectric 368, the sheet-shaped dielectric 368 may be provided between the first fin 366 and the second fins 367a to 367c and the partition portions 370a to 370c, which makes it possible to easily obtain the state in which the space is filled with the dielectric 368. Similarly, the space between the outer conductor 353 and the inner conductor 354 of the input port 352, and the space between the outer conductor 356 and the inner conductor 357 of the output port 355 are filled with the dielectric 368. The dielectric 368 may be, for example, air, PTFE, or the like. In other words, the space between the partition part 370 and the antenna part 365 may be filled with the dielectric 368 having a relative permittivity greater than that of air.

In the filter circuit 350 of the second embodiment as well, the partition part 370 and at least one of the second fins 467a to 467c can be formed as a rod-shaped body, so that it is possible to reduce costs and suppress waste material. In other words, in the filter circuit 350, the material costs and the processing difficulty (man-hours required for processing) can be reduced.

As described above, in accordance with the first embodiment, the filter circuit 50 includes the input port 52, the output port 55, the ground base 58, the antenna base 61, the ground fin (the ground fins 91 and 92), and the antenna fin (the antenna fins 62 and 63). The input port 52 is configured to have the first inner conductor (the inner conductor 54) and the first outer conductor (the outer conductor 53). The output port 55 is configured to have the second inner conductor (the inner conductor 57) and the second outer conductor (the outer conductor 56). The ground base 58 is configured such that the first outer conductor on the input port 52 side is connected to the second outer conductor on the output port 55 side. The antenna base 61 is configured such that the first inner conductor on the input port 52 side is connected to the second inner conductor on the output port 55 side. The ground fin (the ground fins 91 and 92) is configured to extend from the ground base 58 toward the antenna base 61. The antenna fin (the antenna fins 62 and 63) is configured to extend from the antenna base 61 toward the ground base 58 with a gap interposed between themselves and the ground fins. In addition, the antenna fin includes the plurality of first rod-shaped bodies (the antenna fins 62) connected to the antenna base 61. As a result, it is possible to reduce costs and reduce processing waste.

Further, in accordance with the first embodiment, the ground fin includes the second rod-shaped body (the ground fin 91) connected to the ground base 58, and the antenna fin is formed such that the plurality of first rod-shaped bodies (the antenna fins 62) are arranged to surround the second rod-shaped body. As a result, a compact high-frequency filter can be realized.

Further, in accordance with the first embodiment, the gap between the first rod-shaped bodies is determined by the above Equation (4). As a result, the variation in the filter frequency can be controlled.

Further, in accordance with the first embodiment, the plurality of first rod-shaped bodies (the antenna fins 62) of the antenna fin operate as a monopole antenna. As a result, it is possible to reduce costs and suppress processing waste.

Further, in accordance with the first embodiment, the ground fin includes the plurality of third rod-shaped bodies (the ground fins 92) connected to the ground base 58 to surround the plurality of first rod-shaped bodies (the antenna fins 62). As a result, a compact high-frequency filter can be realized.

Further, in accordance with the first embodiment, the gap between the third rod-shaped bodies (the ground fins 92) is defined by the above Equation (4). As a result, the variation in the filter frequency can be controlled.

Further, in accordance with the first embodiment, the antenna fin includes the plurality of fourth rod-shaped bodies (the antenna fins 63) connected to the antenna base 61 to surround the plurality of third rod-shaped bodies (the ground fins 92). As a result, a compact high-frequency filter can be realized.

Further, in accordance with the first embodiment, the plurality of first rod-shaped bodies (the antenna fins 62) and the plurality of fourth rod-shaped bodies (the antenna fins 63) of the antenna fin operate as a multipole antenna. As a result, a compact high-frequency filter can be realized.

Further, in accordance with the first embodiment, the ground base 58 forms part of the housing 51 of the filter circuit 50, and the inside of the housing 51 is filled with the dielectric 66. As a result, a compact high-frequency filter can be realized.

Further, in accordance with the first embodiment, the dielectric 66 has the holes (the holes 91a, 92a, 62a, and 63a) formed to correspond to the ground fin (the ground fins 91 and 92) and the antenna fin (the antenna fins 62 and 63). As a result, the filter circuit 50 can be easily assembled.

Further, in accordance with the second embodiment, the filter circuit 350 includes the input port 352, the output port 355, the ground base (the housing 351), the antenna base 362, the ground fin (the partition part 370), and the antenna fin (the first fin 366 and the second fin 367). The input port 352 is configured to have the first inner conductor (the inner conductor 354) and the first outer conductor (the outer conductor 353). The output port 355 is configured to have the second inner conductor (the inner conductor 357) and the second outer conductor (the outer conductor 356). The ground base is configured such that the first outer conductor on the input port 352 side is connected to the second outer conductor on the output port 355 side. The antenna base 362 is configured such that the first inner conductor on the input port 352 side is connected to the second inner conductor on the output port 355 side. The ground fin is connected to at least one of the first surface (the side surface 360a) of the ground base, to which the first outer conductor on the input port 352 side is connected, and the second surface (the side surface 360b) of the ground base, which faces the first surface and to which the second outer conductor on the output port 355 side is connected, and the ground fin is configured to extend from one of the first surface and the second surface to the other. The antenna fin is configured to extend from the antenna base 362 so as to be stacked with the ground fin with a gap provided between the antenna fin and the ground fin. In addition, the ground fin includes the plurality of first rod-shaped bodies (the partition portions 370a to 370c) connected to at least one of the first surface and the second surface. As a result, it is possible to reduce costs and suppress processing waste. In addition, it is possible to realize a simple and compact high-frequency filter.

Further, in accordance with the second embodiment, the ground base is the housing 351 that is configured such that the internal space expands in the first direction and the second direction perpendicular to the first direction in plan view. Further, the antenna base 362 is located at the center of the housing 351 in plan view. Further, the antenna fin includes the plurality of second rod-shaped bodies (the second fins 467a to 467c) radially connected to the antenna base 362. As a result, it is possible to reduce costs and suppress processing waste.

Further, in accordance with the second embodiment, the gap between the first rod-shaped bodies of the plurality of first rod-shaped bodies (the partition portions 370a to 370c) is defined by the above Equation (4). As a result, it is possible to control the variation in the filter frequency.

The embodiments of the present disclosure are illustrative in all respects and are not restrictive. The above-described embodiments may be omitted, replaced, or changed in various forms without departing from the scope of the appended claims and the gist thereof.

In the above-described first embodiment, the antenna 60 has been described as an example of a multipole antenna, but the present disclosure is not limited thereto. For example, the antenna 60 may further include antenna fins that concentrically surround the antenna fins 62 and 63. In this case, the longitudinal length of the cylindrical shape of the filter circuit 50 can be further shortened, and a more compact high-frequency filter can be realized. For example, by increasing the number of antenna fins from two to four, the longitudinal length of the cylindrical shape of the filter circuit 50 can be reduced to a half while maintaining the filter performance.

In the above-described embodiments, the transmission path length is set to ¼ wavelength of the electromagnetic wave to be blocked, but the present disclosure is not limited thereto. For example, the number and dimensions of the antenna fins and the ground fins that form concentric circles may be set such that the transmission path length in which the traveling waves and the reflected waves cancel each other can be obtained.

In addition, in the above-described embodiments, the filter circuits 50 and 350 are connected to the electrostatic electrode 1111b in the electrostatic chuck 1111, but the present disclosure is not limited thereto. For example, the filter circuits 50 and 350 may be connected to a heater (not shown) provided in the substrate support part 11.

In addition, in the above-described embodiments, the plasma processing apparatus 1 that performs processing such as etching or the like on the substrate W using capacitively coupled plasma as the plasma source has been described as an example, but the present disclosure is not limited thereto. As long as the apparatus performs processing on the substrate W using plasma, the plasma source is not limited to capacitively coupled plasma, and any plasma source such as inductively coupled plasma, microwave plasma, magnetron plasma can be used.

Further, the present disclosure can also include the following configurations.

(1)

A filter circuit comprising:
an input port configured to have a first inner conductor and a first outer conductor;
an output port configured to have a second inner conductor and a second
a ground base configured to connect the first outer conductor of the input port and the second outer conductor of the output port;
an antenna base configured to connect the first inner conductor of the input port and the second inner conductor of the output port;
a ground fin configured to extend from the ground base toward the antenna base; and
an antenna fin configured to extend from the antenna base toward the ground base with a gap provided between the ground fin and the antenna fin,
wherein the antenna fin includes a plurality of first rod-shaped bodies connected to the antenna base.
   (2)

The filter circuit of (1), wherein the ground fin includes a second rod-shaped body connected to the ground base, and
the antenna fin is formed such that the plurality of first rod-shaped bodies are arranged to surround the second rod-shaped body.
   (3)

The filter circuit of (2), wherein a gap between the first rod-shaped bodies is defined by the following equation (A1),

$${d}_{1} < A \frac{{δ}_{2}}{( 1 + {δ}_{2} )} \cdot \frac{λ}{\sqrt{{ε}_{r}}} \qquad ( A 1 )$$

wherein in the equation (A1), d₁ indicates the gap between the first rod-shaped bodies, λ indicates a wavelength of a resonant frequency f₀, εᵣ indicates a relative permittivity of a medium between the ground fin and the antenna fin, δ₂ indicates a variation in the resonant frequency f₀, and A indicates a coefficient based on δ₂.
   (4)

The filter circuit of (2) or (3), wherein the antenna fin is configured such that the plurality of first rod-shaped bodies operate as a monopole antenna.

(5)

The filter circuit of any one of (2) to (4), wherein the ground fin includes a plurality of third rod-shaped bodies connected to the ground base, the plurality of third rod-shaped bodies being arranged to surround the plurality of first rod-shaped bodies.

(6)

The filter circuit of (5), wherein a gap between the plurality of third rod-shaped bodies is defined by the following equation (A2),

$${d}_{2} < A \frac{{δ}_{2}}{( 1 + {δ}_{2} )} \cdot \frac{λ}{\sqrt{{ε}_{r}}} \qquad ( A 2 )$$

wherein in the equation (A2), d₂ indicates the gap between the third rod-shaped bodies, λ indicates a wavelength of a resonant frequency f₀, εᵣ indicates a relative permittivity of a medium between the ground fin and the antenna fin, δ₂ indicates a variation in the resonant frequency f₀, and A indicates a coefficient based on δ₂.
   (7)

The filter circuit of (5) or (6), wherein the antenna fin includes a plurality of fourth rod-shaped bodies connected to the antenna base, the plurality of fourth rod-shaped bodies being arranged to surround the plurality of third rod-shaped bodies.

(8)

The filter circuit of (7), wherein the antenna fin is configured such that the plurality of first rod-shaped bodies and the plurality of fourth rod-shaped bodies operate as a multipole antenna.

(9)

The filter circuit of any one of (1) to (8), wherein the ground base forms a part of a housing of the filter circuit, and the inside of the housing is filled with a dielectric.

(10)

The filter circuit of (9), wherein the dielectric has holes corresponding to the ground fin and the antenna fin.

(11)

A filter circuit comprising:
an input port configured to have a first inner conductor and a first outer conductor,
an output port configured to have a second inner conductor and a second outer conductor,
a ground base configured to connect the first outer conductor of the input port and the second outer conductor of the output port,
an antenna base configured to connect the first inner conductor of the input port and the second inner conductor of the output port,
a ground fin configured to be connected to at least one of a first surface of the ground base, to which the first outer conductor of the input port is connected, and a second surface of the ground base, which faces the first surface and to which the second outer conductor of the output port is connected, the ground fin being configured to extend from one of the first surface and the second surface toward the other; and
an antenna fin configured to extend from the antenna base so as to be stacked with the ground fin with a gap provided between the ground fin and the antenna fin,
wherein the ground fin includes a plurality of first rod-shaped bodies connected to at least one of the first surface and the second surface.
   (12)

The filter circuit of (11), wherein the ground base is a housing having an internal space that is configured to expand in a first direction and a second direction perpendicular to the first direction in plan view,
the antenna base is located at a center of the housing in plan view, and
the antenna fin includes a plurality of second rod-shaped bodies radially connected to the antenna base.
   (13)

The filter circuit of (11) or (12), wherein a gap between the first rod-shaped bodies is defined by the following equation (A3),

$${d}_{3} < A \frac{{δ}_{2}}{( 1 + {δ}_{2} )} \cdot \frac{λ}{\sqrt{{ε}_{r}}} \qquad ( A 3 )$$

wherein in equation (A3), d₃ represents the gap between the first rod-shaped bodies, λ represents a wavelength of a resonant frequency f₀, εᵣ represents a relative permittivity of a medium between the ground fin and the antenna fin, δ₂ represents a variation in the resonant frequency f₀, and A represents a coefficient based on δ₂.
   (14)

A plasma processing apparatus comprising:
a processing chamber; and
a filter circuit provided in a power supply line that supplies a power to an electrode exposed to electromagnetic waves for generating plasma in the processing chamber,
wherein the filter circuit includes:
an input port configured to have a first inner conductor and a first outer conductor;
an output port configured to have a second inner conductor and a second
a ground base configured to connect the first outer conductor of the input port and the second outer conductor of the output port;
an antenna base configured to connect the first inner conductor of the input port and the second inner conductor of the output port;
a ground fin configured to extend from the ground base toward the antenna base; and
an antenna fin configured to extend from the antenna base toward the ground base with a gap provided between the ground fin and the antenna fin,
wherein the antenna fin includes a plurality of first rod-shaped bodies connected to the antenna base.

1. A filter circuit comprising:
an input port configured to have a first inner conductor and a first outer conductor;
an output port configured to have a second inner conductor and a second outer conductor;
a ground base configured to connect the first outer conductor of the input port and the second outer conductor of the output port;
an antenna base configured to connect the first inner conductor of the input port and the second inner conductor of the output port;
a ground fin configured to extend from the ground base toward the antenna base; and
an antenna fin configured to extend from the antenna base toward the ground base with a gap provided between the ground fin and the antenna fin,
wherein the antenna fin includes a plurality of first rod-shaped bodies connected to the antenna base.

2. The filter circuit of claim 1, wherein the ground fin includes a second rod-shaped body connected to the ground base, and
the antenna fin is formed such that the plurality of first rod-shaped bodies are arranged to surround the second rod-shaped body.

3. The filter circuit of claim 2, wherein a gap between the first rod-shaped bodies is defined by the following equation (1),
$$[ Equation 1 ]$$
$${d}_{1} < A \frac{{δ}_{2}}{( 1 + {δ}_{2} )} \cdot \frac{λ}{\sqrt{{ε}_{r}}} \qquad ( 1 )$$
wherein in the equation (1), d₁ indicates the gap between the first rod-shaped bodies, λ indicates a wavelength of a resonant frequency f₀, εᵣ indicates a relative permittivity of a medium between the ground fin and the antenna fin, δ₂ indicates a variation in the resonant frequency f₀, and A indicates a coefficient based on δ₂.

4. The filter circuit of claim 2, wherein the antenna fin is configured such that the plurality of first rod-shaped bodies operate as a monopole antenna.

5. The filter circuit of claim 2, wherein the ground fin includes a plurality of third rod-shaped bodies connected to the ground base, the plurality of third rod-shaped bodies being arranged to surround the plurality of first rod-shaped bodies.

6. The filter circuit of claim 5, wherein a gap between the plurality of third rod-shaped bodies is defined by the following equation (2),
$$[ Equation 2 ]$$
$${d}_{2} < A \frac{{δ}_{2}}{( 1 + {δ}_{2} )} \cdot \frac{λ}{\sqrt{{ε}_{r}}} \qquad ( 2 )$$
wherein in the equation (2), d₂ indicates the gap between the third rod-shaped bodies, λ indicates a wavelength of a resonant frequency f₀, εᵣ indicates a relative permittivity of a medium between the ground fin and the antenna fin, δ₂ indicates a variation in the resonant frequency f₀, and A indicates a coefficient based on δ₂.

7. The filter circuit of claim 5, wherein the antenna fin includes a plurality of fourth rod-shaped bodies connected to the antenna base, the plurality of fourth rod-shaped bodies being arranged to surround the plurality of third rod-shaped bodies.

8. The filter circuit of claim 7, wherein the antenna fin is configured such that the plurality of first rod-shaped bodies and the plurality of fourth rod-shaped bodies operate as a multipole antenna.

9. The filter circuit of claim 1, wherein the ground base forms a part of a housing of the filter circuit, and the inside of the housing is filled with a dielectric.

10. The filter circuit of claim 9, wherein the dielectric has holes corresponding to the ground fin and the antenna fin.

11. A filter circuit comprising:
an input port configured to have a first inner conductor and a first outer conductor,
an output port configured to have a second inner conductor and a second outer conductor,
a ground base configured to connect the first outer conductor of the input port and the second outer conductor of the output port,
an antenna base configured to connect the first inner conductor of the input port and the second inner conductor of the output port,
a ground fin configured to be connected to at least one of a first surface of the ground base, to which the first outer conductor of the input port is connected, and a second surface of the ground base, which faces the first surface and to which the second outer conductor of the output port is connected, the ground fin being configured to extend from one of the first surface and the second surface toward the other; and
an antenna fin configured to extend from the antenna base so as to be stacked with the ground fin with a gap provided between the ground fin and the antenna fin,
wherein the ground fin includes a plurality of first rod-shaped bodies connected to at least one of the first surface and the second surface.

12. The filter circuit of claim 11, wherein the ground base is a housing having an internal space that is configured to expand in a first direction and a second direction perpendicular to the first direction in plan view,
the antenna base is located at a center of the housing in plan view, and
the antenna fin includes a plurality of second rod-shaped bodies radially connected to the antenna base.

13. The filter circuit of claim 11, wherein a gap between the first rod-shaped bodies is defined by the following equation (3),
$$[ Equation 3 ]$$
$${d}_{3} < A \frac{{δ}_{2}}{( 1 + {δ}_{2} )} \cdot \frac{λ}{\sqrt{{ε}_{r}}} \qquad ( 3 )$$
wherein in equation (3), d₃ represents the gap between the first rod-shaped bodies, λ represents a wavelength of a resonant frequency f₀, εᵣ represents a relative permittivity of a medium between the ground fin and the antenna fin, δ₂ represents a variation in the resonant frequency f₀, and A represents a coefficient based on δ₂.

14. A plasma processing apparatus comprising:
a processing chamber; and
a filter circuit provided in a power supply line that supplies a power to an electrode exposed to electromagnetic waves for generating plasma in the processing chamber,
wherein the filter circuit includes:
an input port configured to have a first inner conductor and a first outer conductor;
an output port configured to have a second inner conductor and a second outer conductor;
a ground base configured to connect the first outer conductor of the input port and the second outer conductor of the output port;
an antenna base configured to connect the first inner conductor of the input port and the second inner conductor of the output port;
a ground fin configured to extend from the ground base toward the antenna base; and
an antenna fin configured to extend from the antenna base toward the ground base with a gap provided between the ground fin and the antenna fin,
wherein the antenna fin includes a plurality of first rod-shaped bodies connected to the antenna base.
